(19) United States
(12) Patent Application Publication
(10) Pub. No.: US 2010/0159644 A1
(43) Pub. Date: Jun. 24, 2010

(54) LOW-COST FLIP-CHIP INTERCONNECT WITH AN INTEGRATED WAFER-APPLIED PHOTO-SENSITIVE ADHESIVE AND METAL-LOADED EPOXY PASTE SYSTEM

(76) Inventors: Rajiv Carl Dunne, Murphy, TX (US); Marvin Wayne Cowens, Plano, TX (US); Mario Antonio Bolanos, Plano, TX (US)

Correspondence Address: TEXAS INSTRUMENTS INCORPORATED, P O BOX 655474, M/S 3999, DALLAS, TX, 75265, US

(21) Appl. No.: 12/642,445

(22) Filed: Dec. 18, 2009

Related U.S. Application Data
(60) Provisional application No. 61/139,393, filed on Dec. 19, 2008.

(51) Int. Cl. H01L 21/78; H01L 21/60

(52) U.S. Cl. 438/113; 438/118; 257/E21.506; 257/E21.599

(57) ABSTRACT

Various exemplary embodiments provide materials and methods for flip-chip packaging technology. The disclosed flip-chip packaging technology can use a single B-stage wafer-applied photo-sensitive adhesive along with printed interconnects, which does not include conventional underfill materials and processes. In one embodiment, a photo-sensitive adhesive can be applied on a semiconductor die or a base substrate with conductive bumps printed in through-openings of the photo-sensitive adhesive. One or more semiconductor dies can be laterally packaged or vertically stacked on the base substrate using the printed conductive bumps as interconnects there-between.

### RELATED APPLICATIONS

This application claims priority from U.S. Provisional Patent Applications Ser. No. 61/139,393, filed Dec. 19, 2008, which is hereby incorporated by reference in its entirety.

### FIELD OF THE INVENTION

The invention relates generally to semiconductor device assembly and packaging and, more specifically, to flip-chip packaging of integrated circuit (IC) devices.

### BACKGROUND OF THE INVENTION

In flip-chip packaging processes, when plated metal bumps are used, a photo-resist is first applied on a wafer or semiconductor die. Then, it is exposed and developed to create openings at the bump locations. Subsequently, a conductive material is plated into the passivation openings in the photo-resist to create metal bumps. The conductive material is typically solder, copper, copper plus solder or solder-loaded epoxy paste.

After the flip-chip metal bumps are created, the semiconductor die is attached to the substrate. Due to the presence of the bumps on the semiconductor die, a gap is formed between the substrate and the active surface of the semiconductor die attached thereto. To enhance the joint integrity formed by the metal bumps, an underfill material is introduced in the gap between the semiconductor die and the substrate. The underfill material is applied, for example, post die attachment by capillary underfills, during die attachment by non-conductive paste, or prior to die attachment by laminating on the wafer-level.

In other words, two types of materials are utilized to make a conventional flip-chip joint including: (1) the photo-resist material to create the metal bumps, and (2) the underfill material to support the metal bumps.

### SUMMARY OF THE INVENTION

In addition to using an underfill material to fill the gap between a semiconductor die and a base substrate for a mechanical support, anisotropic conductive films (ACF) and anisotropic conductive pastes (ACP) are used for conventional flip-chip interconnects.

For example, ACF or ACP typically uses Au or other metallic particles that are trapped between top and bottom pads for the semiconductor die and the base substrate to make flip-chip interconnects via mechanical contacts. Due to such mechanical contacts, conventional flip-chip interconnects have reliability problems.

Applicants have therefore realized that new material systems and new methods are needed to provide improved flip-chip interconnects and to reduce manufacturing cost.

For example, solder alloy based materials can be printed to make metallurgical bond with interfaces to form new flip-chip interconnects, which can also be used for applications requiring higher current densities.

In addition, Applicants have discovered a new material for use in an integrated flip-chip packaging process that combines desired material properties of both the photo-resist and the underfill materials. The inventive material can include, for example, a photo-sensitive adhesive including UV (ultra-violet) curable polymeric precursors. The photo-sensitive adhesive can be patterned for printing conductive bumps on a semiconductor die or a base substrate. The printed conductive bumps along with the photo-sensitive adhesive can be formed between the semiconductor die and the base substrate to provide interconnects there-between.

The photo-sensitive adhesive can be cured at any desired point during the flip-chip packaging process. In one example, the photo-sensitive adhesive can be partially cured to support and define the location of the conductive bumps prior to or during their formation. The partially cured material can then be fully cured after the formation of the conductive bumps and/or during the subsequent bonding process between the semiconductor die and the base substrate.

In this manner, the UV curable photo-sensitive adhesive can have an integrated function of conventional photo-resist and the underfill materials for flip-chip packaging technology. The printed conductive bumps can provide robust interconnects between the semiconductor dies and the base substrate.

Additionally, the new material systems and methods can simplify the process flow as compared with conventional packaging processes. Further, the length of the period of manufacturing time can be significantly reduced. Furthermore, manufacturing cost on materials and equipment can also be significantly reduced. For example, the formation of the printed flip-chip bumps can cost less than conventional electro-plated bumps. The elimination of using separate underfill materials can reduce cost for related materials, equipment, and processes.

Even further, the disclosed UV curable photo-sensitive adhesive can include filler particles to reduce mismatch of TEC (thermal expansion coefficient) occurring between the photo-sensitive adhesive and the substrate. Multiple flip-chips can also be packaged in a stacked fashion.

The technical advances represented by the present teachings, as well as the aspects thereof, will become apparent from the following description of the exemplary embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate embodiments of the invention and together with the description, serve to explain the principles of the invention.

FIG. 1 depicts an exemplary flip-chip method in accordance with various embodiments of the present teachings.

FIGS. 2A-2D depict a series of cross-sectional elevation views of a semiconductor device at various packaging stages according to the exemplary method of FIG. 1 in accordance with an embodiment of the present invention.

FIGS. 3A-3C depict another series of cross-sectional elevation views of a semiconductor device at various packaging stages according to the exemplary method of FIG. 1 in accordance with an embodiment of the present invention.

FIG. 4 depicts an exemplary collectively packaged device in relative to FIGS. 1-3 in accordance with various embodiments of the present teachings.

FIG. 5 depicts an exemplary flip-chip packaged semiconductor device in accordance with an embodiment of the present invention.

FIGS. 6A-6F depict a conventional flip-chip process.

FIGS. 7A-7F depict another conventional flip-chip process.

It should be noted that some details of the figures have been simplified and are drawn to facilitate understanding of the inventive embodiments rather than to maintain strict structural accuracy, detail, and scale.

### DESCRIPTION OF THE EMBODIMENTS

Various exemplary embodiments provide materials and methods for flip-chip packaging technology, which uses printed conductive bumps as flip-chip interconnects and is free of a combined use of the photo-resist and the underfill materials as used in the art. Reference will now be made in detail to exemplary embodiments of the invention, examples of which are illustrated in the accompanying drawings. Wherever possible, the same reference numbers will be used throughout the drawings to refer to the same or like parts.

In embodiments, the disclosed flip-chip packaging technology can use a photo-sensitive adhesive that includes curable polymeric precursors. In one embodiment, a photo-sensitive adhesive can be applied on a semiconductor die and/or a base substrate with conductive bumps formed, e.g., printed, in through-openings of the photo-sensitive adhesive. One or more semiconductor dies or a semiconductor wafer with a plurality of semiconductor dies can then be laterally packaged or vertically stacked on the base substrate using the printed conductive bumps as interconnects there-between. The disclosed flip-chip packaging technology does not use the underfill process nor use the plated conductive bumps as known in the art, but use a single B-stage wafer-applied photo-sensitive adhesive along with printed interconnects.

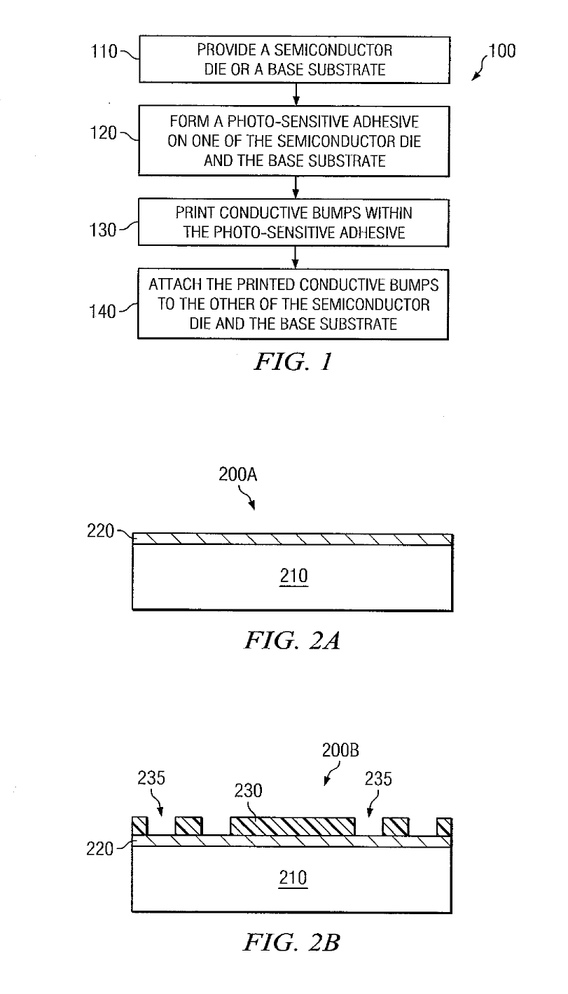

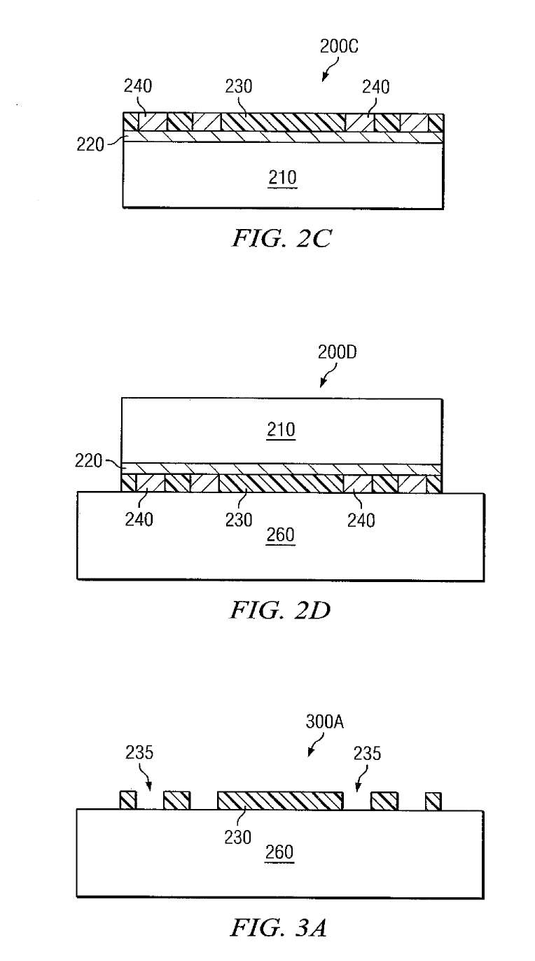

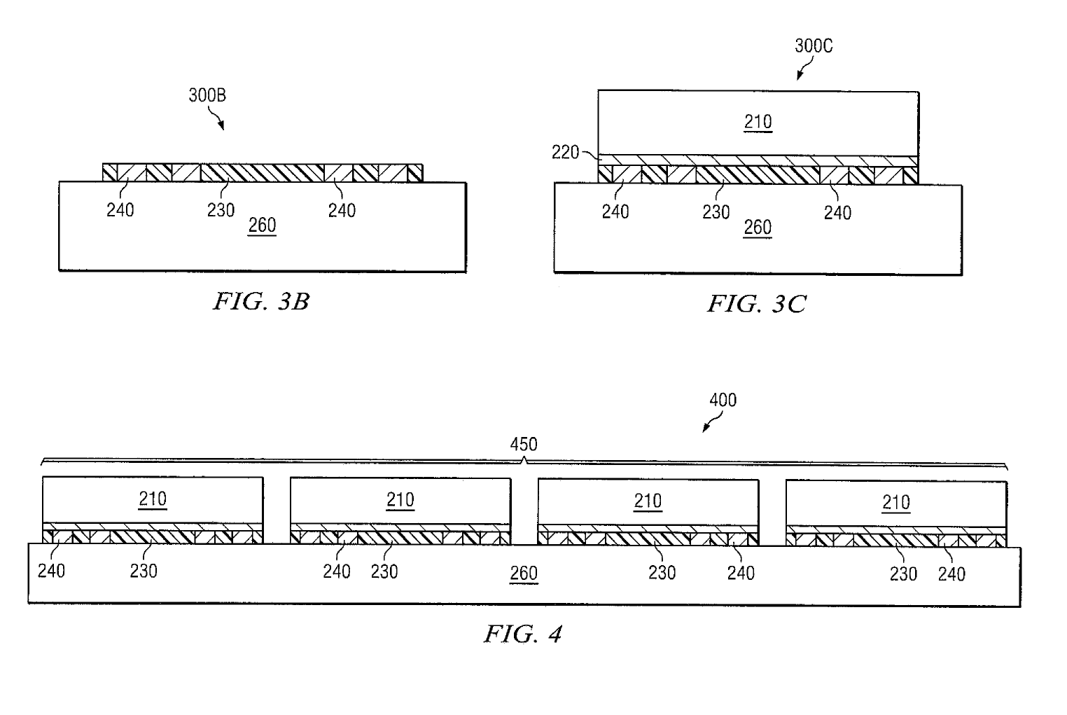

FIG. 1 depicts an exemplary flip-chip method 100 in accordance with various embodiments of the present teachings. FIGS. 2A-2D or FIGS. 3A-3C depict a series of cross-sectional elevation views of a semiconductor device at various packaging stages according to the exemplary method of FIG. 1 in accordance with an embodiment of the present invention.

Note that although the method 100 will be described in reference to FIGS. 2A-2D and/or FIGS. 3A-3C for illustrative purposes, the process of method 100 is not limited to the structures shown in FIGS. 2A-2D and FIGS. 3A-3C. In addition, while the method 100 of FIG. 1 is illustrated and described below as a series of acts or events, it will be appreciated that the present teachings are not limited by the illustrated ordering of such acts or events. For example, some acts may occur in different orders and/or concurrently with other acts or events apart from those illustrated and/or described herein. Also, not all illustrated steps may be required to implement a methodology in accordance with one or more aspects or embodiments of the present invention. Further, one or more of the acts depicted herein may be carried out in one or more separate acts and/or phases.

At 110 of FIG. 1, and as shown in FIG. 2A, a semiconductor die 210 can be provided.

In embodiments, the semiconductor die 210 can have contact pads 220 formed thereon for electrically connecting the semiconductor die 210 with other components of the packaging. Note that although the contact pads 220 is depict as an contact layer over the underlying surface, one of ordinary skill in the art would understand that the contact pads 220 can be patterned contacts to electrically connect active surfaces of the semiconductor die 210 with, for example, corresponding contact pads of a base substrate (see 260 of FIG. 2D) or a panel of the packaging. In embodiments, any known contact pad materials and methods used in semiconductor packaging can be employed for the contact pads 220.

In various embodiments, the semiconductor die 210 can be used for one or more devices of a microprocessor, a digital signal processor, a radio frequency chip, a memory, a microcontroller, an application specific integrated circuit, and a system-on-a-chip or a combination thereof. (or MEMS device)

At 120 of FIG. 1, and as shown in FIG. 2B, a photo-sensitive adhesive 230 can be applied or formed on the semiconductor die 210.

The photo-sensitive adhesive 230 can include a plurality of through-openings 235 with each through-opening corresponding to a location of a subsequently-formed conductive bumps (see 240 in FIG. 2C) over the semiconductor die 210 and through the photo-sensitive adhesive 230. In embodiments, the through-openings 235 and/or the subsequently-formed conducive bumps 240 (see FIG. 2C) can match up with the contact pads of the semiconductor die 210 and/or of the base substrate 260 (see FIG. 2D) for electrical connections and/or physical attachments.

In embodiments, the photo-sensitive adhesive 230 can include, for example, a polymeric precursor of, such as a resin or other suitable materials. In an exemplary embodiment, the photo-sensitive adhesive 230 can include a photo-resist type of material. For example, the photo-sensitive adhesive 230 can be a long chain polymer including, but not limited to, acrylate polymer, aliphatic, aromatic epoxies, phenolic resins, or combinations thereof. In embodiments, the photo-sensitive adhesive 230 can further include a photosensitizing agent, which can be used to crosslink the polymeric precursor to form, for example, thermosetting resins. In embodiments, the photosensitizing agent can be used to initialize the crosslinking reaction by, for example, ultraviolet (UV) energy from a UV source. In embodiments, the photosensitizing agent can include agents that have aromatic rings, and/or conjugated double or triple bonds including, but not limited to, dibenzantronile, tetracene, diphenylanthracene and onium salts.

In embodiments, the photo-sensitive adhesive 230 can be formed by first applying a liquid material, for example, spin-coating a photo-sensitive polymeric precursor liquid, onto the semiconductor die 210 or onto a wafer containing a number of dies. The applied liquid material can then undergo, for example, a development or curing process and/or a consolidation process (e.g., a drying process).

In other embodiments, the photo-sensitive adhesive 230 can be applied by first forming a photo-sensitive polymeric film and then laminating the film onto the semiconductor die 210 or onto a wafer containing a number of dies. In this case, the through-openings 235 can be formed when forming the photo-sensitive polymeric film or after the lamination over the semiconductor die 210.

In embodiments, filler particles including, but not limited to, silica, carbon, ceramic, glass such as solid glass microspheres, or other suitable particles can be dispersed in the polymeric precursor of the photo-sensitive adhesive 230, for example, the thermosetting resins. In embodiments, the filler particles can have a particle size on the order of from nanometers to micrometers. For example, the filler particles can be nanofillers having a particle size of about 1000 nm or less. In embodiments, the filler particles can have a particle size of about 1 nm to about 1 micron or to about 3 microns or greater, or in some cases, from about 1 micron to about 3 microns. In other embodiments, the filler particles can have an average particle size from less than about 0.01 micron to about 30 microns, although other particle sizes can also be included according to the present teachings.

In embodiments, the filler particles can be used to control TEC (thermal expansion coefficient) mismatch that occurs with the base substrate 260 (see FIG. 2D). For example, the inclusion of filler particles can decrease TEC of the photo-sensitive adhesive in order to match with an organic base substrate. Additionally, the filler particles can increase mechanical modulus of the disclosed photo-sensitive adhesive. In embodiments, particle size distribution and percentage of filler particles can be used to control the TEC of the photo-sensitive adhesive 230 and to prevent interference of the filler particles with the photochemistry of the exemplary thermosetting materials. For example, the filler particles can be present in an amount ranging from about 0.1% to about 70% by weight of the photo-sensitive adhesive 230, although other amount of the filler particles can also be used.

In some embodiments, the photo-sensitive adhesive 230 can be at least partially cured (as oppose to a complete cure) as a photo-sensitive adhesive gel with through-openings 235 formed therein. In other embodiments, the photo-sensitive adhesive 230 can be fully cured from the polymeric precursor.

As used herein, the term “photo-sensitive adhesive gel” refers to a point at which the polymeric precursor can be sufficiently cured to provide a mechanical support for the formation of the through-openings 235 and for the subsequent formation of conductive bumps in the through-openings 235. In embodiments, the photo-sensitive adhesive gel can be formed by developing or curing the polymeric precursor with a measurable elastic modulus.

In embodiments, the through-openings 235 can be formed by a patterning process including, for example, imprinting, or stamping, and/or molding the polymeric precursor at one or more stages of its curing process. The polymeric precursor can be patterned, for example, prior to its curing, at a certain point of curing (whereby forming a photo-sensitive adhesive gel), or after a completely curing of the viscous polymeric precursor or the photo-sensitive adhesive gel.

In certain embodiments, the curing or partially curing process of the polymeric precursor can be performed at a temperature of about 150° C. to about 175° C. for a time length ranging from about 60 seconds to about 120 minutes using UV energy at a wavelength from about 350 nm to about 450 nm.

In an exemplary embodiment, free radical UV chemistries can be used for the curing process. For example, the absorption of UV light can cause the photo initiator to split into two free radicals. This can attack the other functional groups within the chemistry such as the monomer or oligomers, and join them together to form a longer polymer chain. For example, acrylate functional groups or carbon-carbon double bonds can be used as the site for the chemical attack. Chemistries can include more than one functional group, for example, di-acrylates and/or tri-acrylates to allow the crosslinking between polymer chains. The reaction can proceed through chain-propagation and termination or completion of the reaction. The process of producing long chain polymers can include the result of exposure to UV light which is called photo-polymerization. Increasing the chain length effectively can harden the material due to the chemical bonding between components within the acrylate structure, for example.

At 130 of FIG. 1, and as shown in FIG. 2C, a plurality of conductive bumps 240 can be formed by filling conductive materials in the through-openings 235 of the photo-sensitive adhesive 230. The photo-sensitive adhesive 230 can be a photo-sensitive adhesive gel, in the embodiments where the polymeric precursors are partially cured over the semiconductor die 210. In embodiments, the conductive bumps 240 (or the through-openings 235) can connect the contact pad 220 attached on the semiconductor die 210.

In embodiments, conductive materials including metals, metal alloys, solder paste, and/or metal-loaded polymer paste, for example, metal loaded epoxy can be printed in the patterned through-openings 235 to form the conductive bumps 240. For example, the conductive bumps 240 can be made by a screen printing, dispensing, or combinations thereof. The metals or metal alloys used herein can include, for example, Pb, Sn, In, Ag, Au, Cu, Ni or combinations thereof. The metal loaded epoxy can include solder, Cu, Ag, or other metal particles as known to one of ordinary skill in the art.

In an exemplary embodiment, the conductive bumps 240 can be formed by screen printing conductive metal pastes (solder alloys, Ag, etc.) or conductive metal-polymer pastes using stencil printer. In embodiments, a dispensing step can be used for the printing, for example, when there are very few bumps.

In embodiments, following the printing process of the exemplary metal-loaded epoxy paste, a consolidation process, for example, a drying process can be performed to form the conductive bumps 240.

The epoxy-based conductive bumps can provide many advantages over conventional materials and methods using anisotropic conductive paste (ACP) or anisotropic conductive film (ACF), where bonding is through mechanical contact of Au or other particles between top and bottom surfaces.

At 140 of FIG. 1, and as shown in FIG. 2D, the device 200C of FIG. 2C can be flipped and then attached to, for example, a base substrate 260 or a panel as known in flip-chip technology. In embodiments, the semiconductor die 210 can be coupled to the base substrate 260 with each conductive bump 240 matching up with contact pads (not illustrated) of the base substrate 260 for the attachment.

In embodiments, because the polymeric precursor is partially cured to be a photo-sensitive adhesive gel at the step of 120 prior to or during the printing of the conductive bumps 240, the photo-sensitive adhesive gel can then be fully cured when the semiconductor chip 210 is flipped and attached to the base substrate 260.

In embodiments, prior to the flip-chip step, the semiconductor die 210 can be singulated from, e.g., a wafer, and then be bonded to the base substrate 260. In embodiments, the bonding or coupling between the flip-chip 210 and the base substrate 260 can be performed using, for example, thermo-compression bonding of individual chips, collective or gang fashion bonding of one or more chips after temporarily tacking the chips in place or other suitable bonding or attachment technologies. In exemplary embodiments, the conductive bumps 240 can be solder bumps that can be melted to form strong bonds with the contact pads (e.g., solder pads) on the base substrate 260.

In embodiments, the base substrate 260 can be made of various materials, organic or inorganic. In embodiments, the base substrate 260 can include, for example, a glass epoxy substrate including a glass-fiber-reinforced epoxy resin, such as FR4, a bismaleimide triazine (BT) substrate, lead frame substrate, a silicon wafer or other substrates formed from suitable materials. For example, the base substrate 260 can be formed from thinner substrates, such as polyimide or ceramic films for high temperature applications, or formed from thicker substrates, such as multilayer substrates (i.e., laminates). In embodiments, the base substrate can be in a form of a strip, a singulated piece, or a reel-to-reel format. In one embodiment, the base substrate 260 can be rectangularly shaped with dimensions, for example, approximately ten inches wide by twelve inches long; or with any suitable shape and any suitable size. In another embodiment, the base substrate 260 can be a silicon wafer having one or more wafers with semiconductor dies stacked on the base substrate wafer for a vertical packaging.

FIGS. 3A-3C depict another embodiment for making a flip-chip interconnect with the integrated wafer-applied photo-sensitive adhesive and metal-loaded epoxy paste system in accordance the method of FIG. 1. This specific embodiment can include materials and methods as similarly described in FIGS. 2A-2D with the exception that the photo-sensitive adhesive 230 and the conductive bumps 235 can be applied to the base substrate 260 first. Flipped semiconductor die 210 can then be printed attached thereto the conductive bumps 235 as shown in FIGS. 3A-3C.

In FIG. 3A, a photo-sensitive adhesive 230 can be patterned on a base substrate 260 to include a plurality of through-openings 235. Conductive bumps 240 can then be printed into the through-openings 235 and on the base substrate 260 as shown in FIG. 3B. A semiconductor chips 210 as shown in FIG. 2A can then be flipped and attached to the conductive bumps 240 to make an electrical interconnect between the semiconductor die 210 and the base substrate 260.

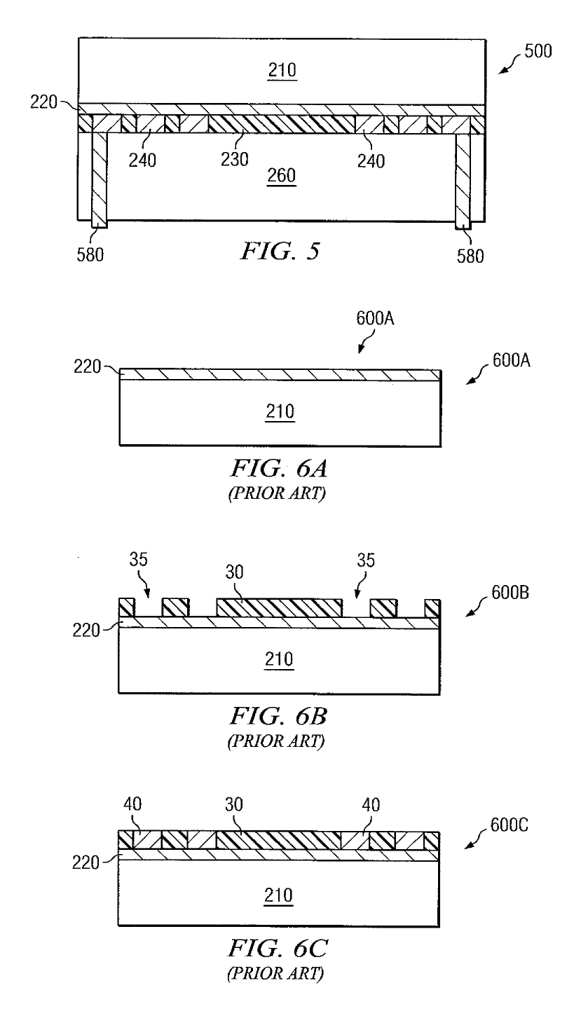

In various embodiments, the methods and structures shown in FIGS. 1-3 can be in a wafer-applied manner, wherein the wafer can include a plurality of semiconductor dies with each die electrically interconnected with the base substrate as shown in FIG. 4. For example, a collective bonding or a gang bonding can be performed to bond a group or all semiconductor dies 210 of a wafer 450 with the base substrate 260. In relative to FIGS. 1-3, the collective bonding of the wafer 450 in FIG. 4 can be performed when the printed conductive bumps 240 and the photo-sensitive adhesive 230 are bonded to the base substrate 260 as shown in FIG. 2D or when the printed conductive bumps 240 and the photo-sensitive adhesive 230 are bonded to the semiconductor die 210 as shown in FIG. 3C. In embodiments, the collective or gang bonding can be performed, for example, after an initial tack process to position each semiconductor dies for the subsequent bonding. In this case, no singulation process can be needed and each semiconductor die on the same wafer 450 can be simultaneously bonded with the base substrate.

In embodiments, in addition to providing a mechanical substrate/support for a semiconductor device and its formation, the base substrate 260 can also provide electrical interconnections between the semiconductor die 210 and external circuits (not shown) for the exemplary devices shown in FIGS. 2A-2D, FIGS. 3A-3C and FIG. 4.

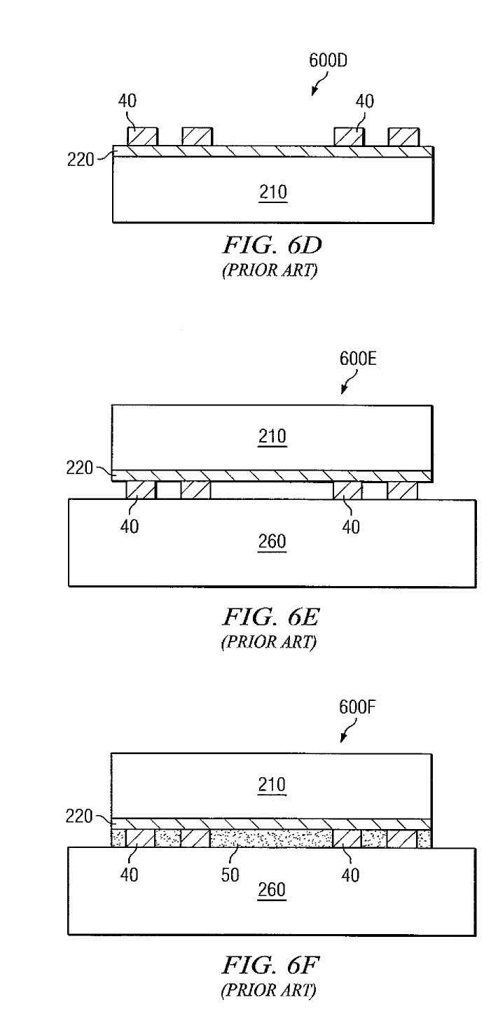

For example, FIG. 5 depicts that one or more electrically conductive paths can be formed in the base substrate 260 of FIGS. 2A-2D, FIGS. 3A-3C and FIG. 4 in accordance with various embodiments of the present teachings. As shown, the base substrate 260 can include interconnect vias 580 made of conductive materials as known in the art, for example, to electrically connect the base substrate 260 with external circuits.

In embodiments, the disclosed flip-chip interconnects with integrated wafer-applied photo-sensitive adhesive and metal-loaded epoxy paste system can be used to vertically stack a plurality of flip-chips, where TSVs (Through Si via) are involved. The bonding process described in FIGS. 2-4 can be applied to the TSV tip side or on a second semiconductor die (not shown).

In embodiments, the methods and structures shown in FIGS. 1-5 can be applied to any package type that uses flip-chip technology including, but not limited to, package-on-package (PoP), multi-chip packages (MCPs), systems in package (SiP), chip scale package (CSP), or quad flat no leads (QFN).

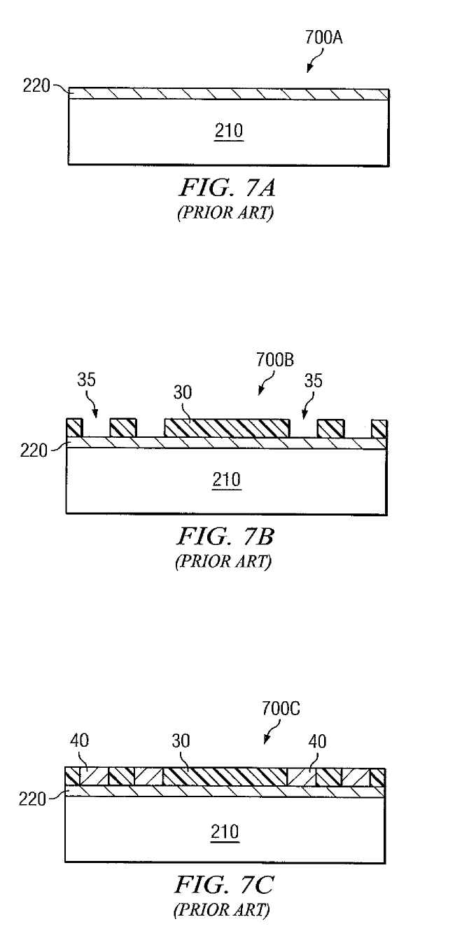

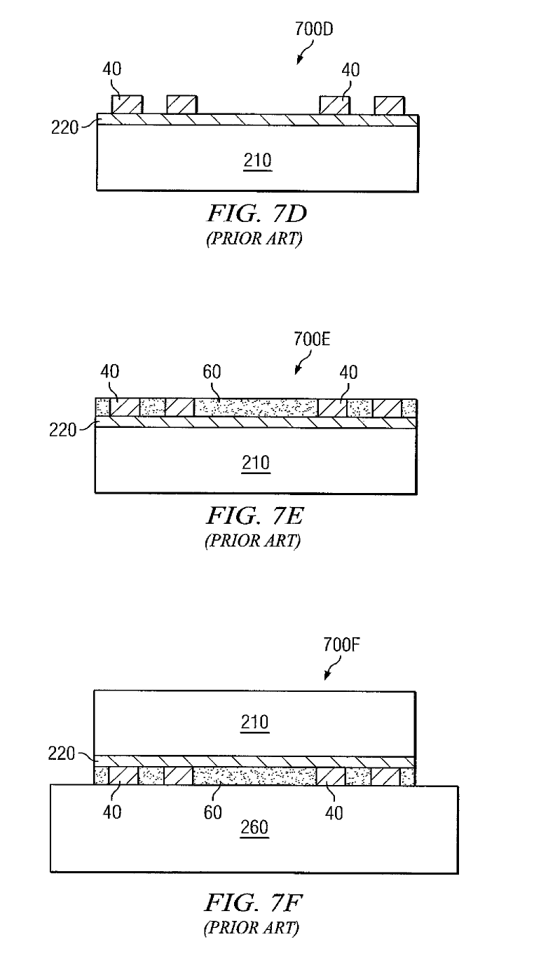

For comparison purpose, FIGS. 6A-6F and FIGS. 7A-7F depict various conventional flip-chip processes.

As shown, a photo-resist 30 (see FIG. 6B) can be formed on the semiconductor die 210 (see FIG. 6A). The photo-resist 30 can be patterned to form a plurality of vias 35 and then cured. Conductive bump materials 40 can be, for example, plated in the vias 35 within the patterned photo-resist 30. Following the formation of the conductive bumps 40, the photo-resist 35 can be removed as shown in FIG. 6D. The device 600D can then be flipped and attached onto a base substrate 260 as shown in FIG. 6E. In FIG. 6F, underfill materials 50 can then be capillarilly dispensed to fill the gap between the semiconductor die 210 and the base substrate 260 and around the conductive bumps 40.

FIGS. 7A-7F shows another conventional process, wherein after the formation of the conductive bumps 40 and after the removal of the patterned photo-resist 30 (see FIGS. 6A-6D and 7A-7D), an underfill film 60 can be laminated onto the semiconductor die 210 surrounding the conductive bumps 40 (see FIG. 7E). The device 700E can then be flipped and attached onto the base substrate 260 having the underfill film 60 there-between (see FIG. 7F).

As compared with the disclosed flip-chip technology shown in FIGS. 1-5, complications due to the material systems used in the conventional processes of FIGS. 6-7 can be substantially reduced. By utilizing the disclosed photo-sensitive adhesive instead of utilizing a combination of the photo-resist materials (e.g., when forming conductive bumps) and the underfill materials (e.g., when coupling flip-chip to the base substrate), the disclosed flip-chip technology can be free of an underfill act or method and can significantly reduce the cost of flip-chip packaging, simplify the manufacturing process (to increase throughout), and eliminate the potential problems known in the art due to use of underfill equipments and materials.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” Further, in the discussion and claims herein, the term “about” indicates that the value listed may be somewhat altered, as long as the alteration does not result in nonconformance of the process or structure to the illustrated embodiment. Finally, “exemplary” indicates the description is used as an example, rather than implying that it is an ideal.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A flip-chip packaging method comprising:
providing a semiconductor die and a base substrate;
applying a photo-sensitive adhesive to one of the semiconductor die and the base substrate; wherein the photo-sensitive adhesive comprises a plurality of through-openings;
printing a conductive bump in each through-opening of the photo-sensitive adhesive; and
attaching the printed conductive bump and the photo-sensitive adhesive to the other of the semiconductor die and the base substrate to interconnect the semiconductor die and the base substrate without removing the photo-sensitive adhesive.

2. The method of claim 1, wherein attaching the printed conductive bump and the photo-sensitive adhesive avoids use of an underfill process.

3. The method of claim 1, wherein printing a conductive bump further comprises screen printing a metal paste or a metal-loaded polymer paste in each through-opening of the photo-sensitive adhesive.

4. The method of claim 1, wherein applying a photo-sensitive adhesive to one of the semiconductor die and the base substrate further comprises spin-coating a polymeric precursor liquid or laminating a polymeric precursor film on the semiconductor die or the base substrate.

5. The method of claim 1 further comprising controlling a TEC (thermal expansion coefficient) of the photo-sensitive adhesive by including a plurality of filler particles in the photo-sensitive adhesive to reduce a TEC mismatch occurring with the base substrate.

6. The method of claim 1, wherein the plurality of filler particles comprises carbon, ceramic, or glass particles and is present in an amount ranging from about 0.1% to about 70% by weight of the total photo-sensitive adhesive.

7. The method of claim 1, wherein the base substrate is a silicon wafer, a ceramic substrate, a glass epoxy organic substrate, a bismaleimide triazine (BT) substrate, a lead frame substrate or a multilayer substrate.

8. The method of claim 1, wherein the base substrate is in a form of a strip, a singulated piece, or a reel-to-reel format.

9. The method of claim 1 further comprising:
at least partially curing a polymeric precursor of the photo-sensitive adhesive on one of the semiconductor die and the base substrate prior to printing the conductive bump; and
fully curing the polymeric precursor when attaching the printed conductive bump and the photo-sensitive adhesive to the other of the semiconductor die and the base substrate.

10. The method of claim 1, wherein applying a photo-sensitive adhesive to one of the semiconductor die and the base substrate further comprises patterning a polymeric precursor at one or more stages of: prior to a curing of the polymeric precursor, or at a point of at least partially curing the polymeric precursor.

11. The method of claim 1 further comprising singulating the semiconductor die or the base substrate prior to the attaching step.

12. The method of claim 1, wherein attaching the printed conductive bump and the photo-sensitive adhesive to the other of the semiconductor die and the base substrate comprises one or more processes of a thermo-compression bonding, a solder bonding or a collective bonding to interconnect the semiconductor die and the base substrate.

13. The method of claim 1, wherein the photo-sensitive adhesive comprises one or more materials of acrylate polymer, aliphatic epoxy, aromatic epoxy, phenolic resin and a combination thereof.

14. The method of claim 1, wherein the photo-sensitive adhesive comprises a photosensitizing agent that has aromatic rings, conjugated double bonds, or conjugated triple bonds and that comprises dibenzantronile, tetracene, diphenylanthracene or onium salts.

15. A flip-chip packaging method comprising:
providing a wafer that comprises a plurality of semiconductor dies;
applying a photo-sensitive adhesive to each of the plurality of semiconductor dies; wherein the photo-sensitive adhesive comprises a plurality of through-openings;
printing a conductive bump in each through-opening of the photo-sensitive adhesive; and
collectively bonding the plurality of semiconductor dies of the wafer to a base substrate to form an interconnect between each semiconductor die and the base substrate by the printed conductive bump without removing the photo-sensitive adhesive and without using an underfill material.

16. The method of claim 15, further comprising controlling a TEC (thermal expansion coefficient) mismatch occurring between the photo-sensitive adhesive and the base substrate by including a plurality of filler particles in the photo-sensitive adhesive.

17. The method of claim 15, wherein printing a conductive bump further comprises screen printing a metal paste or a metal-loaded polymer paste in each through-opening of the photo-sensitive adhesive.

18. A flip-chip packaging method comprising:
providing a semiconductor die and a base substrate;
forming a photo-sensitive adhesive gel on one of the semiconductor die and the base substrate; wherein the photo-sensitive adhesive gel comprises a plurality of through-openings;
printing a metal-loaded epoxy paste in each through-opening of the photo-sensitive adhesive to form a conductive bump;
attaching the photo-sensitive adhesive gel and the conductive bump onto the other of the semiconductor die and the base substrate to provide an interconnect between the semiconductor die and the base substrate; and
fully curing the photo-sensitive adhesive gel.

19. The method of claim 18, wherein attaching the photo-sensitive adhesive gel and the conductive bump onto the other of the semiconductor die and the base substrate precludes use of a photo-resist and an underfill material.

20. The method of claim 18, wherein forming a photo-sensitive adhesive gel comprises partially curing a polymer precursor on one of the semiconductor die and the base substrate, wherein the polymer precursor comprises a thermosetting polymeric precursor and a plurality of filler particles dispersed therein to provide a TEC (thermal expansion coefficient) of the photo-sensitive adhesive.

21. The method of claim 18, wherein the semiconductor die is one of a plurality of semiconductor dies on a wafer and each semiconductor die is simultaneously attached to the base substrate.
